(19) United States
(12) Patent Application Publication
(10) Pub. No.: US 2015/0219874 A1
(43) Pub. Date: Aug. 6, 2015

(54) COOLING SYSTEM FOR AT LEAST ONE SYSTEM COMPONENT OF AN OPTICAL SYSTEM FOR EUV APPLICATIONS AND SYSTEM COMPONENT OF THIS TYPE AND OPTICAL SYSTEM OF THIS TYPE

(71) Applicant: Carl Zeiss SMT GmbH, Oberkochen (DE)

(72) Inventor: Stacy Figueredo, Oberkochen (DE)

(21) Appl. No.: 14/684,727

(22) Filed: Apr. 13, 2015

Related U.S. Application Data
(63) Continuation of application No. PCT/EP2013/075051, filed on Nov. 29, 2013.
(60) Provisional application No. 61/731,010, filed on Nov. 29, 2012.

(51) Int. Cl. G02B 7/18; G03F 7/20; G02B 5/08

(52) U.S. Cl. CPC G02B 7/181; G02B 5/0891; G03F 7/70891

(57) ABSTRACT

A cooling system for at least one system component of an optical system for EUV applications comprises at least one cooling channel and a cooling medium for passing through the at least one cooling channel, absorbing heat from the at least one system component and for carrying off the heat. The cooling medium comprises a dielectric fluid, excluding pure water, 1,1,1,2-Tetrafluoroethane (R134a) and Chlorodifluoro-methane (R22).The dielectric fluid comprises a liquid phase at an operating pressure below 10 bar and in a temperature range of approximately 10° C. to approximately 50° C.

The invention relates to a cooling system for at least one system component of an optical system for EUV applications, comprising at least one cooling channel and comprising a cooling medium for passing through the at least one cooling channel, absorbing heat from the at least one system component and for carrying off the heat.

The invention additionally relates to a system component of an optical system for EUV applications and to an optical system for EUV applications comprising a cooling system of the types mentioned above.

A cooling system and also a system component and an optical system for EUV applications are known from the document U.S. Pat. No. 7,591,561 B2, and from the document U.S. 2012/0267550 A1 for example.

An optical system for EUV applications within the meaning of the present invention is, in particular, an EUV projection exposure apparatus or a subsystem of such an EUV projection exposure apparatus.

A system component of such an EUV projection exposure apparatus within the meaning of the present invention is, in particular, an optical element, in particular a mirror.

A projection exposure apparatus for lithography is used for example for producing finely structured electronic components. An EUV projection exposure apparatus operates with short-wave radiation, to be precise with radiation in the extreme ultraviolet, abbreviated to EUV radiation, the wavelength of which is in the range of approximately 5 nm to approximately 20 nm, for example.

In the case of an optical system for EUV applications, a technical problem that arises is that in particular the optical elements of the optical system heat up to a great extent on account of being subjected to EUV radiation. The heat input leads to heating of the optical elements, with the consequence that the optical elements can deform during operation. The deformation of just a single optical element can result in undesired imaging aberrations of the optical system.

Therefore, cooling systems have been proposed which serve to carry off the heat input into the optical system during operation on account of the action of the EUV radiation from individual or all system components of the optical system in order to provide for corresponding cooling. However, the cooling of an optical system in present-day EUV lithography systems is difficult on account of the high heat flow density on the optical elements and the relatively high thermal resistance of the optical elements and on account of the requirement for stability in relation to deformations of the optical elements. In order to prevent critical components and materials from being overheated, the cooling medium must be able to remove heat from the system to a sufficient extent, which depends on the material selection and on the performance settings of the system.

The document U.S. Pat. No. 7,591,561 B2 cited in the introduction proposes providing a plurality of cooling channels in the optical element or in the optical elements, a cooling medium being passed through the cooling channels, which cooling medium is not specified in more specific detail therein, apart from the fact that it is intended to be an arbitrary suitable fluid or liquid which is conductive and has a relatively high heating capacity.

Known cooling systems for optical systems for EUV applications use, inter alia, cooling media such as mixtures of water and glycol, for example. The use of coolants such as glycol or water-glycol mixtures entails the risk of contaminations of the system components, in particular of the optical elements of the optical system.

Further disadvantages of known cooling systems for optical systems for EUV applications include the fact that the cooling media used often have a corrosive action in relation to the system components, which typically comprise materials such as copper and aluminum.

Low-temperature cooling, for example using liquid nitrogen, has also been proposed, but this has the disadvantage that the low cooling temperature is significantly lower than the ambient temperature of the optical system, which is normally at the usual room temperature, as a result of which a high outlay has to be expended with regard to the thermal insulation of the cooling system from the surroundings.

The document U.S. 2012/0267550 A1 discloses a cooling system which is configured as a two-phase cooling system, i.e. the cooling medium used is present in the gaseous (vapor) and in the liquid state in the system. This document proposes to use the following fluids as cooling fluids: ammonia, H₂S, CO₂, R32, Propane, R22, 2-butane, R41, N₂O, Ethane, Propylene, DME and R134a. Most of these fluids require a pressure for a saturation temperature at 22° C. which is higher than 10 bar which poses high requirements for ensuring leak-tightness of the cooling system and, accordingly, requires a higher structural outlay of the cooling system. Some of the fluids proposed as cooling media in this document are dielectric fluids, for example R22 and R134a.

Further disadvantages of conventional cooling systems include the risk of condensation, relatively large thermal gradients in the feeding region for the cooling medium, and the risk of thermally governed deformations of critical system components.

It is an object of the present invention to develop a cooling system of the types mentioned in the introduction to the effect that firstly it is able to effectively carry off heat from the optical system or its system components, and secondly involves little outlay and manages without low temperatures such as in the case of low-temperature cooling.

According to a first aspect of the invention, this object is achieved with respect to the cooling system by virtue of the fact that the dielectric fluid comprises a liquid phase at an operating pressure below 10 bar and in a temperature range of approximately 10° C. to approximately 50° C.

Dielectric fluids as cooling media for optical systems for EUV applications generally have the advantage that, at the desired operating temperature of EUV systems, that is to say in the range of approximately 20° C. to approximately 22° C., they have thermal properties which enable an increased heat transfer and an increased heat carrying off capability in comparison with air or nitrogen gas in the case of single-phase cooling. Dielectric fluids have the major advantage over pure water that they have a better compatibility with the materials of the system components, such as copper and aluminum, for example, and in particular have a less corrosive action if they come into contact with typical structure materials such as copper and aluminum. For this reason, pure water, which can be regarded as a dielectric fluid, is excluded from selection as a cooling medium according to the invention since its absorption of gases such as CO₂ leads to impaired material compatibility and thus to a higher risk of corrosion.

A further advantage of a dielectric fluid as a cooling medium is that, owing to the lack of conductivity of a dielectric fluid, electronic components of the optical system are not damaged in the case of leakage during which cooling medium escapes.

However, not all available dielectric fluids are a good option for use in a cooling system for EUV applications, because many of the available dielectric fluids have a very low boiling point at atmospheric pressure (around 1 bar) and, thus, require to operate the fluid under a high operating pressure in order to have a sufficient portion of the fluid in the liquid phase or as a mixture of liquid and gaseous phases. It is to be noted that the maximum system operating pressure is an important criterion when selecting the cooling medium due to structural outlay reasons. Therefore, the present invention provides that a dielectric fluid is selected as the cooling medium which comprises a liquid phase at an operating pressure below 10 bar and in a temperature range of approximately 10° C. to approximately 50° C., preferably in a temperature range of approximately 15° C. to approximately 35° C.

Furthermore according to the invention the dielectric fluid preferably is non-flammable, which reduces or even completely avoids the risk of fire in comparison with conventional cooling media such as ammonia or glycol.

The cooling medium of the cooling system according to the first aspect of the invention can consist of a single dielectric fluid, or the cooling medium can be dielectric fluid as component of a mixture with other cooling media.

In a preferred configuration, the dielectric fluid is selected from the group comprising: (Trans)-1-Chloro-3,3,3-trifluoropropene (R1233zd(E)), 2,3,3,3-Tetrafluoropropene (R1234yf), 1,3,3,-Tetrafluoropropene (R1234ze), 1,1,1,3,3,3-Hexafluoropropane (R236fa), 1,1,13,3-Pentafluoropropane (R245fa), Dodecafluoro-2-methylpentan-3-one (Novec 649);1- Methoxyheptafluoropropane (Novec 7000), Methoxy-nonafluorobutane (Novec 7100), Ethoxy- nonafluorobutane (Novec 7200), Pentane,1,1,1,2,2,3,4,5,5,5-decafluoro-3-methoxy-4-(trfluoromethyl)-(Novec 7300), Hexane,3,ethoxy-1,1,1,2,3,4,4,5,5,6,6,6-dodecafluoro-2-(trifluoromethyl)hexane (Novec 7500), Tetradecafluoro-2-methylhexan-3-one Tetradecafluoro-2,4-dimethylpentan-3-one (Novec 774), 1,1,1,2,2,3,3,4,4,5,5,6,6,6-tetradecafluorohexan (FC 72), Perfluorotri-N-Butylamine (FC 43), Perfluorotripentylamine (FC 70), Perfluorotripropylamine (FC 3283).

The afore-mentioned dielectric fluids are principally suitable cooling media for EUV systems, and these fluids are liquid in the above-mentioned pressure and temperature ranges. Further, these fluids can be used in two-phase cooling as well as in single-phase cooling.

Although all afore-mentioned dielectric fluids are principally usable in a cooling system for EUV applications, it is further preferred if the dielectric fluid has a saturation pressure in a range below 10 bar and above 0.8 bar at a temperature of approximately 22° C.

As already mentioned above, not all of the available dielectric fluids have a saturation pressure in the afore-mentioned pressure and temperature range, but have a saturation pressure much below atmospheric pressure, and, thus require a very high operating pressure to be in the liquid phase in single-phase cooling. When fluids with a very low saturation pressure at the mentioned temperature are used in two-phase cooling (vapor and liquid), the operating pressure of the fluid is much below atmospheric pressure meaning that air contamination into the cooling system can occur even for a minor leak. Further, using dielectric fluids operating under vacuum conditions requires special degasing equipment for collecting and removing the gases at the condenser where they do not condense with the liquid phase of the dielectric fluid. However, these degasing systems remove some of the working fluid in this process, and hence also require a make-up fluid system to add additional working fluid. Additionally, to remove moisture entering a cooling system, an additional component for absorbing the moisture is required. Therefore, the use of sub-atmospheric dielectric fluids is not the best option in cooling an optical system for EUV applications.

Preferred dielectric fluids according to the present invention which have a saturation pressure in a range below 10 bar and above 0.8 bar at a temperature of approximately 22° C. are R1233zd(E), R1234yf, R1234ze, R236fa, R245fa.

Among these dielectric fluids, R1233zd(E) is particularly preferred, because this fluid has a saturation pressure of 1.14 bar at a temperature of 22° C. Thus, when using this dielectric fluid in two-phase cooling, the cooling system can be operated under an operating pressure of slightly above atmospheric pressure, thus avoiding the risk of air contamination upon a leakage of the system. R1234yf has a saturation pressure of 6.18 bar, R1234ze 4.45 bar, R236fa 2.46 bar and R245fa 1.32 bar at a temperature of 22° C., thus R245fa and R236fa are also useful in this aspect.

The dielectric fluid in the at least one cooling channel can be present in a single phase, that is to say in the liquid phase, or it can be present in two phases, that is to say as a mixture of liquid and gaseous phases.

If the cooling medium is present in a liquid phase (single-phase cooling) or as a mixture of liquid and gaseous phases (two-phase cooling), it is possible to make use of the effect, in particular, that the cooling medium can absorb the heat from the at least one system component in the phase transition from liquid to gaseous as latent heat, to be precise with a very high heat capacity and correspondingly small increase in the temperature of the cooling medium. Dielectric fluids having a high latent heat at a temperature of approximately 25° C. are R1233zd(E) (191.1 kJkg⁻¹), R1234yf (143.9 kJkg⁻¹), R1234ze (167.1 kJkg⁻¹), R236fa (145.9 kJkg⁻¹) and R245fa (190.3 kJkg⁻¹) so that these dielectric fluids are not only suited because of their saturation pressure at a temperature in a range of approximately 18° C. to 30° C., but also in view of their high latent heat. Another dielectric fluid which has a high latent heat is Novec 7000 (142.0 kJkg⁻¹ at 25° C.).

Paricularly preferred in two-phase cooling are R1233zd(E) and R245fa.

Non-flammable dielectric fluids are obtainable whose boiling point is in the range around 30° C. at atmospheric pressure, which is particularly advantageous in the context of the present invention because the abovementioned effect according to which the cooling medium can absorb the heat from the at least one system component as latent heat can be utilized in the range of the desired operating temperature of the optical system and in particular at ambient pressure. This means that the cooling system can maintain a stable temperature of the at least one system component or of the optical system around the desired operating temperature of the optical system, without the cooling medium having to be pressurized for this purpose.

The phase of the dielectric fluid can thus vary during heat exchange. It also goes without saying that the phase of the cooling medium can differ in different sections of the cooling system, and even within a specific section it can vary with time or when system parameters of the optical system vary. The cooling medium can assume different phases (liquid, gaseous) during storage, during feeding to a system component to be cooled, and after discharging of the cooling medium after absorption of heat from the at least one system component. In this case, the phase of the cooling medium can differ both from a temporal standpoint and from a spatial standpoint in the cooling system.

In a further preferred configuration, the dielectric fluid in the at least one cooling channel is under an operating pressure which corresponds approximately to atmospheric pressure.

Atmospheric pressure should be understood here to mean the usual external ambient pressure of the optical system, which can be in the range of approximately 800 mbar and 1300 mbar depending on the geographical location of the optical system. It goes without saying that the at least one system component itself can be under other pressures; by way of example, the at least one system component can be operated under vacuum conditions.

If the cooling medium can be operated at atmospheric pressure or at a pressure slightly elevated relative to atmospheric pressure in accordance with the pump pressure, the measures for ensuring the leak-tightness of the cooling system involve a significantly lower outlay compared with the case where the cooling medium is under a pressure significantly elevated relative to atmospheric pressure.

It is likewise preferred if the dielectric fluid in the at least one cooling channel has a temperature which is in a range of approximately 10° C. to approximately 50° C., preferably in a range of approximately 15° C. to approximately 35° C.

The advantage here is that, in contrast to low-temperature cooling, significantly less outlay has to be expended for the temperature conditioning of the dielectric fluid and for the insulation.

With the aim of being able to utilize the abovementioned effect according to which the cooling medium can absorb the heat from the at least one system component as latent heat (two-phase cooling), in a further preferred configuration it is provided that the dielectric fluid has a boiling point in a temperature range of approximately 10° C. to approximately 50° C., preferably in a temperature range of approximately 15° C. to approximately 35° C., at atmospheric pressure. If the cooling medium is operated only in a single phase, higher boiling points are of course possible and also desired, e.g. boiling points >30° C. through to above 200° C., e.g. 215° C.

Dielectric fluids which have a boiling point in the afore-mentioned temperature ranges at atmospheric pressure and, thus, are advantageous are R1233zd (E) (18.4° C. at 1 bar), R245fa (14.8° C. at 1 bar), Novec 649 (49° C. at 1 bar), Novec 7000 (34° C. at 1 bar).

In this configuration, therefore, the effect of absorbing heat as latent heat in two-phase cooling can advantageously be utilized at temperatures around the desired operating temperature of the optical system.

In a further preferred configuration, the dielectric fluid has a dielectric strength in a range of approximately 10 MV/m to approximately 70 MV/m.

The dielectric strengt strength is a measure of the minimum electrical voltage that results in a sparkover, the electrical voltage being present between two electrodes which are at a specific distance apart from one another and between which the dielectric fluid is present. For the cooling system according to the invention, therefore, a dielectric fluid having a high dielectric strength is chosen, which does not lead to a short circuit upon contact with current-carrying parts in the case of leakage.

In a further preferred configuration, the dielectric fluid has a dynamic viscosity in a range of approximately 100 μPa·s to approximately 25.000 μPa·s at a temperature of approximately 22° C. and at atmospheric pressure.

A low dynamic viscosity has the advantage that the decrease or drop in pressure along the at least one cooling channel is as small as possible.

In two-phase cooling applications (latent heat transfer), and in particular in passive cooling applications, e.g. thermosiphon cooling loop systems, the dynamic liquid viscosity and the density ratio between the liquid phase and the gaseous phase are important parameters. They affect considerably the system pressure drop and cooling capacity, the latter being dependent on the mass flow rate in the cooling loop. An ideal cooling medium would have a high density ratio (high cooling capacity) and low viscosity (low pressure drop). The dielectric fluids Novec 649, Novec 7000, Novec 1100, Novec 7200, Novec 7300, Novec 7500, Novec 7774, FC72, FC43, FC70 and FC3283 as well as Ethanol and Methanol have higher density ratios than the dielectric fluids R1233zd (E), R1234yf, R1234ze, R236fa, R245fa, which enhances the flow rate, but also have a higher viscosity which diminishes the flow rate.

For example, comparing the dielectric fluid FC72 with R245fa and R1233zd (E), the first seems to be better for a termosiphon loop system, since it has a higher density ratio and lower viscosity in a state where the gaseous or vapor phase amounts to 40% of the vapor-liquid mixture. The pressure drop for FC72 is very low, but only for low mass flow rates, while at high mass flow rates, the pressure drop is strongly increasing. On the other hand, there are dielectric fluids like R1234yf, R1234ze and R236fa which have a higher pressure drop than FC72, while their pressure drop as a function of the mass flow rate is more or less constant, but at low mass flow rates, their pressure drop is higher than for FC72. On the other hand, while FC72 has a high density ratio, which means a potentially higher mass flow rate in a thermosiphon loop, its pressure drop is similar to the values obtained for R245fa and R1233zd(E) at low mass flow rates and higher at high mass flow rates. Thus, the potential benefit associated with a higher density ratio is offset by a higher pressure drop.

In preferred configurations of the cooling system according to the invention, a mass flow rate of the cooling medium is in a range of approximately 2 kg/h to approximately 30 kg/h.

In a further preferred configuration, a pressure drop in the cooling system is in a range of approximately 10 Pa to approximately 250 Pa.

It is further preferred, if a change of a pressure drop as a function of a mass flow rate is less than 8 Pa/(kg/h)), preferably in a range of approximately 0.3 Pa/(kg/h)) to approximately 3 Pa/(kg/h)).

For single-phase cooling, in one exemplary embodiment, use is made of a non-flammable dielectric fluid which is liquid at atmospheric pressure and a temperature in the range of approximately 15° C.-30° C. and has a dynamic viscosity of between approximately 0.3 cP and 1000 cP at 22° C. and atmospheric pressure and a dielectric strength of 10 MV/m to approximately 70 MV/m.

In one exemplary embodiment for two-phase cooling, use is made of a non-flammable dielectric fluid which has a boiling point of between 15° C. and 45° C. in addition to the abovementioned parameters of the fluid for single-phase cooling.

According to another aspect of the present invention, the above-mentioned object is achieved with respect to the cooling system according to which the cooling medium comprises the dielectric fluid R134a, by virtue of the fact that the dielectric fluid is present in the at least one cooling channel in liquid phase only.

According to this aspect of the invention, the dielectric fluid R134a is used as the cooling medium, but only in single-phase cooling. Since R134a has a saturation pressure of 6.08 bar at a temperature of 22° C., the cooling system can be operated under an operating pressure which is higher than atmospheric pressure, but not too high in terms of structural outlay requirements for achieving leak tightness. For single-phase cooling, the specific heat (higher values mean higher cooling capacity when considering constant mass flow rate and gradient of cooling medium temperature) and viscosity (associated with the cooling system pressure drop and, consequently, the pumping power in pumped cooling systems) are relevant parameters. In this regard, the dielectric fluid R134a shows a high specific heat at a temperature of 25° C. of 1424.6 JK¹kg⁻¹ which is higher than the specific heat of the other above-mentioned dielectric fluids. Also the dynamic or liquid viscosity of R134a is sufficiently high in order to obtain a good cooling result (202.3 μPa·s). Thus, R134a is particularly advantageous in single (liquid) phase cooling in EUV systems.

In a preferred configuration of the afore-mentioned aspect, the cooling medium is under an operating pressure of more than approximately 6.1 bar, preferably less than approximately 10 bar, and at a temperature in a range of approximately 10° C. to approximately 30° C.

Further, it is preferred if a mass flow rate of the cooling medium is in the range of approximately 2 kg/h to approximately 30 kg/h.

Further, it is preferred if a pressure drop in the cooling system is in a range of approximately 10 Pa to approximately 250 Pa.

In particular, a pressure drop in the cooling system when using R134a as the cooling medium, is obtainable in this range.

Further, it is preferred, if a change of pressure drop as a function of a mass flow rate is less than 8 Pa/(kg/h)), preferably in a range of approximately 0.3 Pa/(kg/h)) to approximately 3 Pa/(kg/h)).

In particular, R134a shows almost no change of the pressure drop as a function of the mass flow rate.

The at least one cooling channel of the cooling system according to the invention can be integrated into the optical system or a structure of the optical system, which should be understood to mean e.g. a chamber in which the optical system or the at least one system component is arranged or a plate on which the optical system or the at least one system component is arranged, or into the at least one system component, or the at least one cooling channel can be arranged in a heat sink, which is thermally conductively connected to the structure or the optical system or the at least one system component or which absorbs heat from the at least one system component by thermal radiation, convection or gas conduction. However, it is likewise possible within the scope of the invention for the at least one cooling channel of the cooling system to serve only for feeding the cooling medium toward the at least one system component, while the system component to be cooled is then at least partly dipped into the cooling medium in the manner of a bath or dipping bath and the cooling medium washes around the system component to be cooled.

A system component according to the invention of an optical system for EUV applications comprises a cooling system according to the invention according to one or more of the configurations mentioned above.

In this case, a system component according to the invention is preferably an optical element, a mechanical element, an actuator and/or a sensor.

An optical element for EUV applications is in particular a mirror, which should also be understood to mean a segmented mirror and an individual mirror segment of a segmented mirror.

A mechanical element can be for example a mount or holder of an optical element.

An actuator can have the function for example of positionally adjusting one or more optical elements of the optical system, or deforming an optical element in a targeted manner.

The cooling system according to the invention can be integrated into arbitrary system components of the optical system or be assigned to them, without the need for a specific spatial orientation of the at least one cooling channel with respect to the optical system or the system components thereof.

An optical system according to the invention for EUV applications, which comprises at least one system component of the types mentioned above, comprises at least one cooling system according to the invention according to one or more of the configurations mentioned above.

Such an optical system according to the invention can be a subsystem of an EUV projection exposure apparatus for lithography or the entire EUV projection exposure apparatus.

In the case where the optical system is a subsystem of an EUV projection exposure apparatus for lithography, the subsystem can be a radiation generating system, an illumination system, a projection system, a reticle system and/or a wafer system.

In the case where the subsystem is a radiation generating system, the collector mirror, for example, can be cooled by the cooling system according to the invention. The illumination system of an EUV projection exposure apparatus is situated between the radiation generating system and the projection system, which contains the projection objective. The reticle system contains the reticle and the associated reticle stage together with actuator system, and the wafer system comprises the wafer and the wafer stage and the associated actuator system.

The cooling system according to the invention can be integrated into one or each of the abovementioned subsystems, or cool the respective subsystem from outside.

Further advantages and features are evident from the following description and the accompanying drawing.

It goes without saying that the features mentioned above and those yet to be explained below can be used not only in the combination respectively indicated, but also in other combinations or by themselves, without departing from the scope of the present invention.

Exemplary embodiments of the invention are illustrated in the drawing and are described in greater detail below with reference to the drawing, in which:

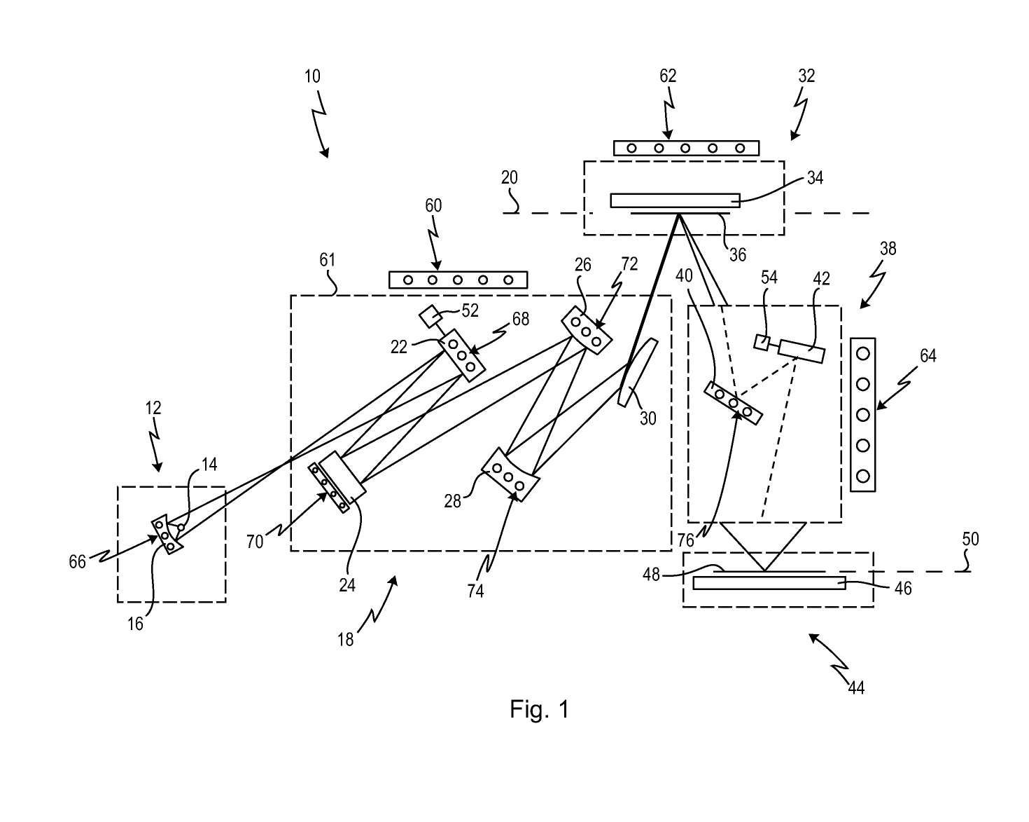

FIG. 1 shows an optical system in the form of an EUV projection exposure apparatus in a schematic illustration;

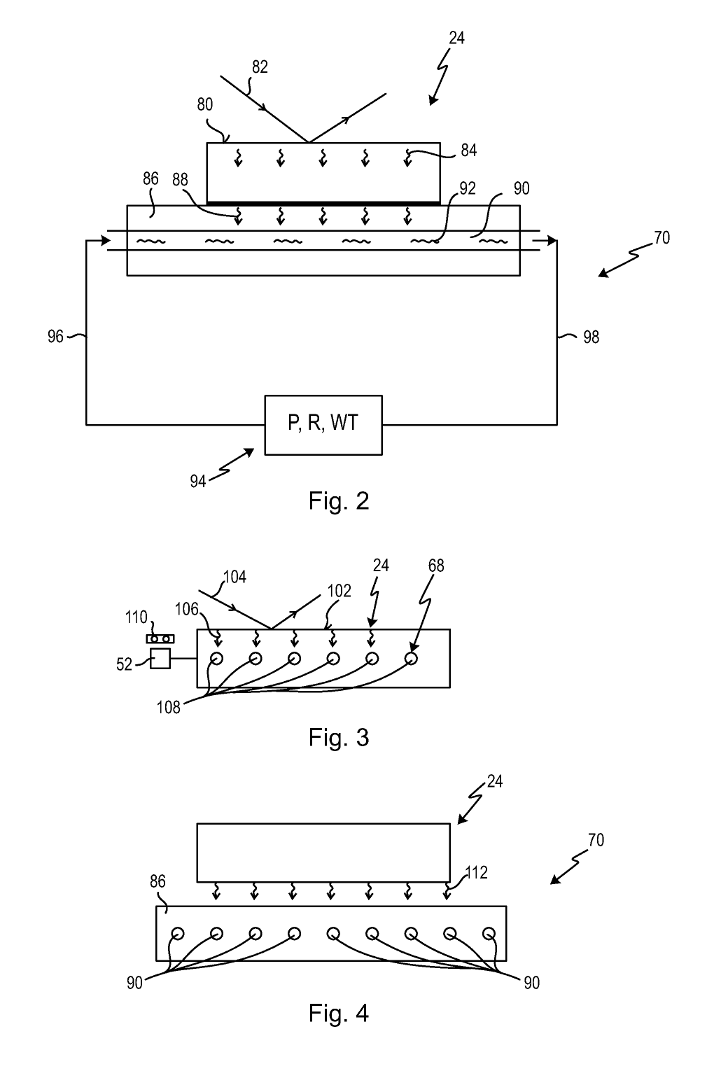

FIG. 2 shows a cooling system for a system component of the optical system in FIG. 1 in a schematic illustration;

FIG. 3 shows a further exemplary embodiment of a cooling system for a system component of the optical system in FIG. 1;

FIG. 4 shows yet another exemplary embodiment of a cooling system for a system component of the optical system in FIG. 1;

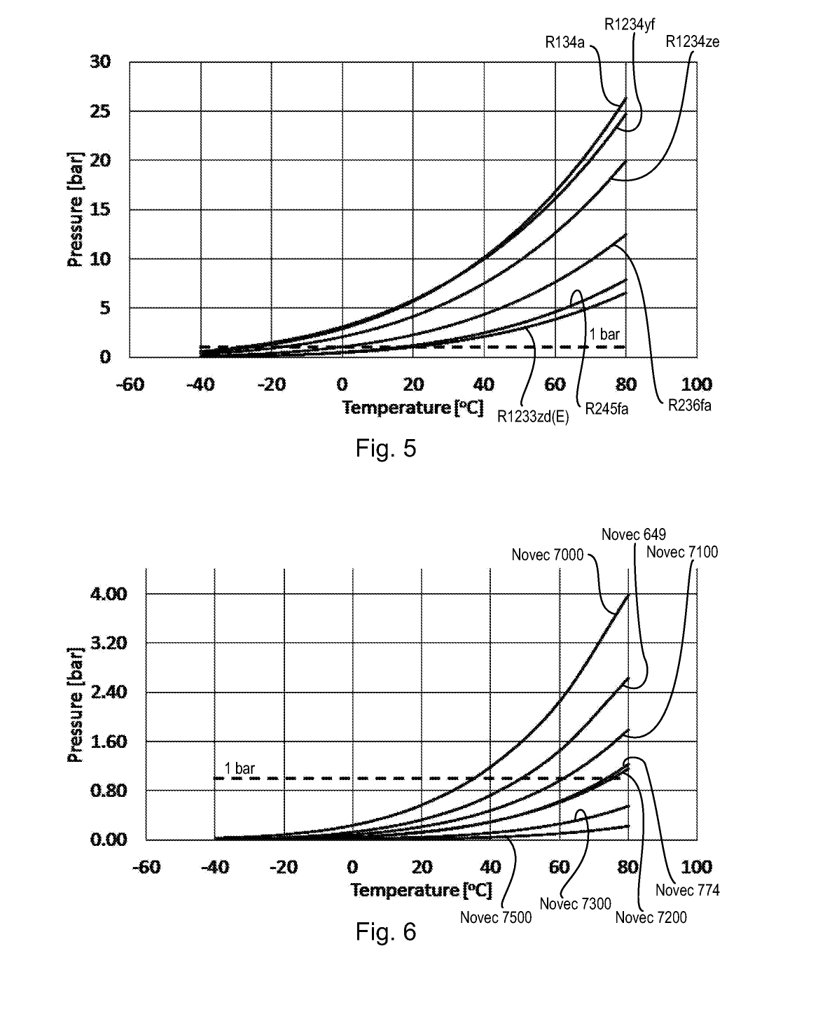

FIG. 5 shows a diagram of saturation curves for six dielectric fluids;

FIG. 6 shows another diagram of saturation curves for seven further dielectric fluids;

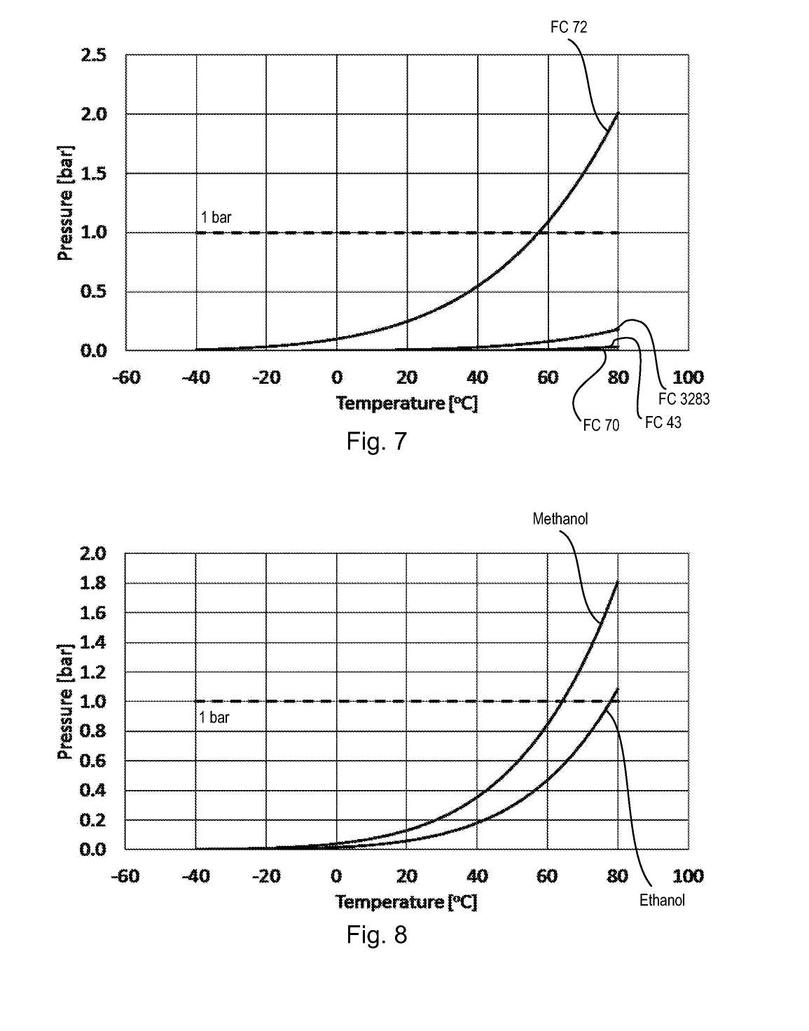

FIG. 7 shows a further diagram of saturation curves for four further dielectric fluids;

FIG. 8 shows a further diagram of saturation curves for methanol and ethanol; and

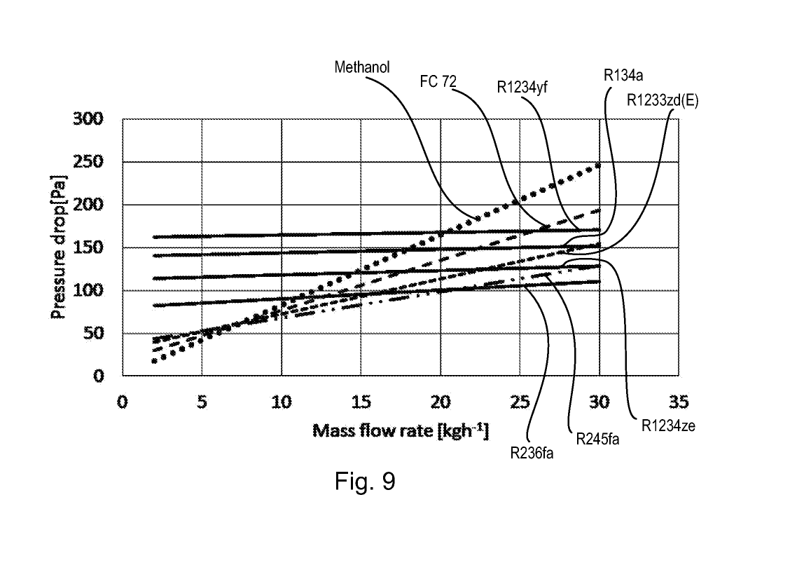

FIG. 9 shows a diagram of pressure drops for eight dielectric fluids as a function of the mass flow rate.

FIG. 1 illustrates an optical system labeled with the general reference number 10. In the exemplary embodiment shown, the optical system 10 is an EUV projection exposure apparatus for lithographically producing semiconductor components.

The EUV projection exposure apparatus comprises a radiation generating system 12 for generating EUV radiation. The radiation generating system 12 has a radiation source 14 and a collector mirror 16 as system components. An illumination system 18 is disposed downstream of the radiation generating system 12 in the radiation propagation direction, the illumination system serving for beam shaping, beam homogenization and generation of a predetermined radiation field in an object plane 20.

The illumination system 18 here has mirrors 22, 24, 26, 28 and 30, for example, as system components.

Furthermore, a reticle system 32 is disposed downstream of the illumination system 18 as seen in the radiation propagation direction, the reticle system having a reticle stage 34 and a reticle 36 as system components, the reticle being arranged in the object plane 20.

Furthermore, a projection system 38 is disposed downstream of the reticle system 32 as seen in the radiation propagation direction, the projection system being embodied in the form of a projection objective. The projection system 38 here has mirrors 40 and 42, for example, as system components.

Finally, a wafer system 44 is disposed downstream of the projection system 38, the wafer system having a wafer stage 46 and a wafer 48 as system components, the wafer being arranged in an image plane 50.

Via the EUV radiation, a pattern of the reticle 36 is imaged on the wafer 48 by the projection system 38.

Alongside the optical elements embodied here in the form of the mirrors 16, 22, 24, 26, 28, 30, 40 and 41, the optical system 10 or the optical subsystems 12, 18 and 38 can have mechanical elements such as mounts or holders for the optical elements, here the mirrors 16, 22, 24, 26, 28, 30, 40, 42, and actuators for manipulating the optical elements, for example for positional adjustment or deformation, wherein FIG. 1 shows two actuators 52 (for the mirror 22) and 54 (for the mirror 42) of this type.

The optical system 10 furthermore comprises one or more cooling systems in order to cool the entire optical system 10, or the above-described individual optical subsystems 12, 18, 32, 38, 44, and/or in order to cool individual or all of the above-described system components of the optical subsystems 12, 18, 32, 38, 44.

FIG. 1 shows by way of example a cooling system 60 for cooling the illumination system 18, a cooling system 62 for cooling the reticle system 32 and a cooling system 64 for cooling the projection system 38.

The cooling systems 60, 62 and 64 cool the illumination system 18, the reticle system 32 and the projection system 38 as a whole and, for example, establish a thermally stable environment for the system components contained in the subsystems. However, it is likewise possible to assign to individual system components cooling systems which can be part of the external cooling systems 60, 62, 64 or can constitute separate cooling systems. Cooling systems of this type are shown here by way of example for the collector mirror 16 (cooling system 66), the mirrors 22, 24, 26, 28 of the illumination system 18 (cooling systems 68, 70, 72, 74), and the mirror 40 (cooling system 76) of the projection system 38. It is likewise possible, as shown by way of example for the illumination system 18, to cool a structure 61, which is e.g. the chamber of the illumination system, via the cooling system 60.

In this case, as illustrated, the cooling systems 66, 68, 70, 72, 74, 76 can be partly integrated into the system components (mirrors 16, 22, 26, 28, 40), for example into the mirror substrates thereof, or can have heat sinks, as shown for the mirror 24, which are thermally conductively connected to the mirrors or arranged at a distance therefrom and absorb thermal radiation from the mirrors.

FIG. 2 shows the mirror 24 in FIG. 1 with the associated cooling system 70 by themselves.

The mirror 24 has a mirror surface 80 on which EUV radiation 82 is incident during operation. The incident EUV radiation 82 leads to a heat input into the mirror 24, as is indicated by heat arrows 84.

The cooling system 70 has a heat sink 86, which is thermally conductively connected to the mirror 24 and correspondingly absorbs heat from the mirror 24 via heat conduction, as is indicated by heat arrows 88.

The heat sink 86 has at least one cooling channel 90 through which a cooling medium 92 is passed.

The cooling system 70 furthermore has here units combined under the general reference sign 94, such as a pump P for circulating the cooling medium 92, a reservoir R for the cooling medium 92 and a heat exchanger WT for absorbing heat from the cooling medium 92 and the like. The abovementioned units 94 can be present in an external machine assembly, wherein further parts of the cooling system 70, such as a unit for conditioning the cooling medium 92, for example, can be provided there.

The cooling medium 92 is fed into the at least one cooling channel 90 via a feed line 96, and discharged from the at least one cooling channel 90 via a discharge line 98.

The cooling medium 92 generally comprises a non-flammable dielectric fluid, excluding pure water.

The non-flammable dielectric fluid is based, in particular, on fluorocarbon or perfluorocarbon or a hydrofluoroether (HFE).

A dielectric fluid based on perfluorocarbon is, for example, a dielectric fluid from the Fluorinert™ series from 3M. Specific further examples of preferred dielectric fluids will be described later.

Dielectric fluids are generally available with a large number of different boiling points, and allow either a single-phase application, in which the dielectric fluid remains in the liquid phase despite absorbing heat, or two-phase applications, in which the fluid boils in the course of absorbing heat and in this case can absorb additional heat in the form of latent heat without a further increase in the temperature of the fluid.

In this case, the cooling medium 92 can comprise or consist of only one specific dielectric fluid, or the dielectric fluid can be a subcomponent of the cooling medium 92, which can then also comprise other substances suitable for cooling, in particular other dielectric fluids.

The dielectric fluid in the at least one cooling channel 90 can be present only in a liquid phase, only in a gaseous phase, or as a mixture of liquid and gaseous phases. The dielectric fluid in the at least one cooling channel 90 is under a pressure corresponding approximately to atmospheric pressure. Also in the feed line 96 and/or the discharge line 98, the dielectric fluid is preferably under a pressure corresponding approximately to atmospheric pressure.

The dielectric fluid in the at least one cooling channel 90 has a temperature which is in a range of approximately 10° C. to approximately 50° C., preferably in a range of approximately 15° C. to approximately 35° C.

As dielectric fluid for two-phase cooling, in particular one used for the cooling medium 92 is such that it has a boiling point in a temperature range of approximately 15° C. to approximately 50° C., preferably in a temperature range of approximately 25° C. to approximately 35° C., at atmospheric pressure.

The dielectric fluid is preferably liquid in a temperature range of approximately 10° C. to approximately 50° C., preferably in a temperature range of approximately 15° C. to approximately 35° C.

Furthermore, the dielectric fluid used for the cooling medium 92 has a dielectric strength in a range of approximately 10 MV/m to approximately 70 MV/m. The cooling medium 92 preferably has a dielectric strength in the range of approximately 10 MV/m to approximately 30 MV/m.

The dynamic viscosity of the dielectric fluid used for the cooling medium 92 is advantageously in a range of approximately 100 μPa·s to approximately 25.000 μPa·s at a temperature of approximately 22° C. and at atmospheric pressure.

As already mentioned above, the cooling medium 92 can be operated in particular in the phase transition between the liquid phase and the gaseous phase, and moreover in a temperature range which is significantly below the boiling point of water, and moreover at atmospheric pressure, such that the cooling medium 92 does not have to be pressurized.

As a result of heat absorption from the mirror 24 or the heat sink 86, the absorbed heat leads to the partial evaporation of the initially liquid cooling medium 92, the absorbed heat being stored as latent heat in the cooling medium 92 without resulting in an increase in temperature or appreciable increases in temperature of the cooling medium 92. Moreover, only a small expansion of the cooling medium 92 occurs in this case.

It goes without saying that the state of matter of the cooling medium 92 in the feed line 96, the at least one cooling channel 90 and the discharge line 98 can be identical, but also different. In this regard, it is possible for the cooling medium 92 to be present in the liquid phase in the at least one cooling channel 90, while it evaporates upon absorbing heat from the mirror 24 and is present at least partly in the gaseous phase in the discharge line 98. It is likewise possible for the cooling medium 92 also to be present as a mixture of liquid and gaseous phases in the at least one cooling channel 90.

Finally, it is also possible for the cooling medium 92 to be present only in the gaseous phase in the at least one cooling channel 90.

For single-phase cooling, in one exemplary embodiment, use is made of a non-flammable dielectric fluid which is liquid at atmospheric pressure and a temperature in the range of approximately 15° C.-30° C. and has a dynamic viscosity of between approximately 0.3 cP-1000 cP at 22° C. and atmospheric pressure and a dielectric strength of between 10 MV/m and approximately 50 MV/m.

In one exemplary embodiment for two-phase cooling, use is made of a non-flammable dielectric fluid which has a boiling point of between 15° C.-45° C. in addition to the abovementioned parameters of the fluid for single-phase cooling.

A non-flammable dielectric fluid for use as the cooling medium 92 has the major advantage, inter alia, that it has no or only little corrosive action in relation to typical materials of the above-described system components, such as copper and aluminum, for example, as a result of which the service life of the optical elements is increased. The fact that the dielectric fluid is non-flammable prevents any risk of fire that can be brought about for example by leakage occurring in the cooling system and the cooling medium 92 coming into contact with regions of the optical system that are regulated at high temperature. The lack of electrical conductivity of the cooling medium 92 on account of the use of a dielectric fluid for the cooling medium 92 has the further advantage that electronic components or circuits which come into contact with the cooling medium in the case of leakage are not short-circuited.

Many perfluorocarbon-based dielectric fluids are moreover harmless, in particular non-toxic, for humans, which poses a problem for other cooling media containing ammonia or glycol, for example. A hydrofluoroether (HFE) can also be used as dielectric cooling medium.

While in the exemplary embodiment in FIG. 2 the at least one cooling channel 90 is arranged in the heat sink 86, which is thermally conductively connected to the system component in the form of the mirror 24, FIG. 3 shows an exemplary embodiment of the cooling system 68 which is assigned to the system component in the form of the mirror 22 in FIG. 1 and is partly integrated into this.

In FIG. 3, a mirror surface of the mirror 22 is provided with the reference sign 102, EUV radiation 104 being applied to the mirror surface during operation, which leads to a corresponding heat input in the mirror 22 (heat arrows 106).

In this exemplary embodiment, the cooling system 68 is partly integrated into the mirror 22, that is to say that the cooling system 68 has one or a plurality of cooling channels 108 integrated into the mirror 22 near the mirror surface 102.

As cooling medium for passing through the cooling channels 108, use is once again made of a cooling medium which comprises a non-flammable dielectric fluid, excluding pure water, as was described with reference to FIG. 2.

The cooling system 68 can additionally be used partly for cooling the actuator system 52, as is indicated by the reference sign 110.

FIG. 4 shows a modification of the cooling system 70 in FIG. 2, wherein in this modification the mirror 24 is not thermally conductively connected to the heat sink 86, but rather is spaced apart from the heat sink 86, and wherein the heat sink 86 absorbs heat from the mirror 24 in the form of thermal radiation (heat arrows 112). Here a plurality of cooling channels 90 are present in the heat sink 86 and the cooling medium 92 (see FIG. 2) flows through them, the cooling medium once again comprising a non-flammable dielectric fluid, excluding pure water.

The dimensions, geometry, length and the configuration of the at least one cooling channel 90 and of the cooling channels 108 are non-critical and can be adapted to the respective purpose. Moreover, the flow rate of the cooling medium 92 and/or the operating pressure of the cooling medium 92 can vary within the respective system to be cooled, for example the optical systems 12, 18, 32, 44, or in the associated system components, for example the mirrors 24 and 22, for example also in a manner dependent on the operating parameters of the optical system 10.

The mirrors 24 and 22 can be embodied as segmented mirrors, for example, wherein the cooling system 70 or 68 can in each case be embodied as a common cooling system for all the mirror segments or only for individual mirror segments.

Furthermore, it goes without saying that the cooling systems 60, 62 and 64 can be embodied in the manner described above for the cooling system 70.

In a further modification (not illustrated), it is likewise possible that e.g. in the exemplary embodiment in accordance with FIG. 2 only the feed line 96 and the discharge line 98 are embodied as cooling channels, while a dipping bath or bath into which the cooling medium 92 is introduced is arranged instead of the cooling channel 90. In this case, the system component 24 can then dip wholly or partly into the bath, in which case the cooling medium 92 then flows or washes around the system component.

In the following, further embodiments of dielectric fluids which can be used in the cooling systems 62, 64, 66, 68, 70, 72, 74, 76 are described.

According to a first group of such embodiments, the cooling medium 92 comprises a dielectric fluid, which preferably is non-flammable, but which is not pure water, 1,1,1,2-tetrafluoroethane (R134a) and not chlorodifluoromethane (R22). According to this aspect of embodiments, the dielectric fluid comprises a liquid phase at an operating pressure below 10 bar and in a temperature range of approximately 10° C. to approximately 50° C., preferably in a temperature range of approximately 15° C. to approximately 35° C.

Preferably, the dielectric fluid is selected from the group comprising the following substances: (Trans)-1-Chloro-3,3,3-trifluoropropene (R1233zd(E)), 2,3,3,3-Tetrafluoropropene (R1234yf), 1,3,3,-Tetrafluoropropene (R1234ze), 1,1,1,3,3,3-Hexafluoropropane (R236fa), 1,1,13,3-Pentafluoropropane (R245fa), Dodecafluoro-2-methylpentan-3-one (Novec 649);1- Methoxyheptafluoropropane (Novec 7000), Methoxy-nonafluorobutane (Novec 7100), Ethoxy-nonafluorobutane (Novec 7200), Pentane,1,1,1,2,2,3,4,5,5,5-decafluoro-3-methoxy-4-(trfluoromethyl)-(Novec 7300), Hexane,3,ethoxy-1,1,1,2,3,4,4,5,5,6,6,6-dodecafluoro-2-(trifluoromethyl)hexane (Novec 7500), Tetradecafluoro-2-methylhexan-3-one Tetradecafluoro-2,4-dimethylpentan-3-one (Novec 774), 1,1,1,2,2,3,3,4,4,5,5,6,6,6-tetradecafluorohexan (FC 72), Perfluorotri-N-Butylamine (FC 43), Perfluorotripentylamine (FC 70), Perfluorotripropylamine (FC 3283).

All the afore-mentioned dielectric fluids are generally usable in cooling applications for EUV optical systems, with some of these dielectric fluids being more advantageous than others, when considering two-phase cooling and single-phase cooling.

According to another embodiment, the cooling medium 92 comprises 1,1,1,2-tetrafluoroethane (R134a), and in this embodiment. R134a is operated in single-phase (liquid) only.

Table 1 (at the end of the description) lists the relevant thermophysical properties of the afore-mentioned dielectric fluids as well as of water, CO₂ (R744), Ethanol and Methanol. The thermophysical properties listed in Table 1 are the saturation temperature Tₛₐₜ at an operating pressure of 1 bar; the saturation pressure Pₛₐₜ at a temperature of 22° C., which is an operating temperature of interest for EUV lithography systems; the triple point; the critical temperature T_{critical}; the critical pressure P_{critical}; the density ratio, which is the ratio between the density of the liquid (vapor) phase and the density of the gaseous phase; the viscosity in a two-phase condition with 40% vapor phase; the liquid viscosity; the liquid density; the latent heat at a temperature of 25° C.; the specific heat at a temperature of 25° C.; the dielectric strength for a 0.25 cm gap; the dielectric constant; and the Global Warming Potential (GWP).

FIGS. 5 through 8 show diagrams of saturation curves for the fluids listed in table 1. Each saturation curve corresponds to the phase boundary between the gaseous (vapor) phase (below the corresponding saturation curve) and the liquid phase (above the corresponding saturation curve).

FIG. 5 shows the saturation curves for the dielectric fluids R134a, R1234yf, R1234ze, R236fa, R245fa, and R1233zd(E). As can be seen from FIG. 5, all the afore-mentioned dielectric fluids comprise a liquid phase in the preferred temperature range of approximately 15° C. to approximately 35° C.

FIG. 6 shows the saturation curves for the dielectric fluids Novec 7000, Novec 649, Novec 7100, Novec 774, Novec 7200, Novec 7300, and Novec 7500.

FIG. 7 shows the saturation curves for the dielectric fluids FC 72, FC 3283, FC 43, and FC 70.

Finally, FIG. 8 shows the saturation curves for Methanol and Ethanol.

On the basis of the saturation curves in FIGS. 5 through 8, the level of pressure that a potential two-phase cooling system will operate at (as either a passive thermosiphon or active pumped cooling system) can be evaluated, in particular in the temperature range of interest, which is the temperature range of approximately 15° C. to approximately 35° C., preferably at a temperature around 18° C. to around 23° C., which is the preferred operating temperature range of an EUV lithography system. It can be taken from FIGS. 6 through 8 that Ethanol, Methanol and all the fluids the saturation curves of which are shown in FIGS. 6 and 7 will work in two-phase cooling applications below the atmospheric pressure in the considered temperature range, meaning that air contamination into the cooling system can occur even for minor leaks. Instead, the fluids the saturation curves of which are shown in FIG. 5 have a positive operating pressure, i.e. an operating pressure which is higher than atmospheric pressure, i.e. between 1.3 bar and 6 bar at a temperature around 20° C. In comparison, CO₂ as cooling medium requires a very high operating pressure in order to be at least in part in liquid phase, because the saturation pressure of CO₂ is about 60 bar at a temperature of 22° C. Such a high operating pressure would require a very high structural outlay in order to ensure leak tightness of the cooling system.

With respect to the criterion of an operating pressure slightly above atmospheric pressure in two-phase cooling, and thus a positive operating pressure, the dielectric fluids R1233zd (E) and R245fa are particularly suited as a cooling medium, but also the dielectric fluids R1234yf, R1234ze, and R236fa.

However, the choice of a dielectric fluid as the cooling medium 92 not only depends on a well-suited operating pressure, but other parameters such as density and viscosity must also be considered when choosing the cooling medium, since these parameters have strong effect in the system pressure drop, i.e. pumping power in pumped cooling systems.

Another parameter which is relevant for the choice of a suited dielectric fluid is the dielectric strength which is indicated in Table 1 for the fluids listed there, and which better represents the electrical insulation property of the fluid than the dielectric constant, because the high dielectric constant does not mean that the fluid has a good electrical insulation characteristic. With respect to the dielectric strength, all the dielectric fluids listed in Table 1 are suitable.

Another relevant parameter, in particular for two-phase cooling applications is the latent heat of the cooling medium. In Table 1, the latent heats at a temperature of 25° C. of the dielectric fluids of interest are indicated. The higher the latent heat, the higher the potential of cooling capacity.

With respect to the latent heat, the dielectric fluids R1233zd (E), R1234yf, R1234ze, R236fa, R245fa are more advantegeous than the Novec fluids except Novec 7000 which shows a latent heat in the same order of magnitude as the aforementioned fluids. While water, Ethanol and Methanol have by far the highest values of latent heat, use of these fluids require operating pressures of about 0.03 bar, 0.08 bar and 0.2 bar for a saturated condition at 25° C., and thus huge two-phase frictional pressure drops lead to highly unstable processes.

For passive cooling applications, e.g. thermosiphon loop cooling systems, the liquid or dynamic viscosity and the density ratio, which means the ratio of the density of the liquid phase to the density of the vapor or gaseous phase, are important parameters. These parameters affect considerably the system pressure drop and cooling capacity (mass flow rate in the cooling loop). An ideal cooling medium would have a high density ratio (high cooling capacity) and low viscosity (low pressure drop). The Novec and FC dielectric fluids as well as Ethanol and Methanol have the highest density ratios which enhances the flow rate, but also a high viscosity which diminishes the flow rate.

In this regard, the dielectric fluid FC 72 seems to be better for a thermosiphon cooling system since it has a higher density ratio and lower viscosity than R245fa and R1233zd (E), and methanol (which however, is highly flammable and toxic) also seems to be a good option, but has a viscosity higher than the other three afore-mentioned dielectric fluids. The negative aspect of the fluids FC 72 and methanol is the operating pressure (about 0.27 bar and about 0.15 bar, respectively), which is below atmospheric pressure, which is not the case for R245fa and R1233zd (E) which can be operated at 1.32 bar and 1.14 bar. As already mentioned above, cooling media operating under vacuum conditions have the disadvantage of air contamination in case of leakage and of requiring special degasing equipment.

With reference to FIG. 9, the effects of density ratio and viscosity on the performance of a cooling medium in a thermosiphon cooling system are described. The pressure drop ΔP in an adiabatic vertical pipe (riser) of 20 cm height (L) and 1 cm of diameter D) was calculated as a function of the mass flow rate. The pressure drop ΔP was determined considering frictional and gravitational terms and an adiabatic two-phase flow (40% of vapor quality), as shown in the following equation:

$$Δ P = ρ g Δ h + f \frac{ 8 {m}^{2}}{{π}^{2} ρ} \frac{L}{{D}^{5}} , \qquad ( 1 )$$

wherein ρ is the density, g the gravity of Earth, Δh the difference in height, m the mass and f the friction factor which was determined assuming laminar fully developed flow (64/Reynolds).

As can be taken from FIG. 9, the pressure drops for methanol and FC 72 were the lowest only for low mass flow rate, being the R245fa the lowest for mass flow rates higher than 7.5 kgh⁻¹. It can also be noted that the higher pressure fluids, i.e. R1234yf, R134a, R1234ze and R236fa, show a more uniform pressure drop, being the values comparable with those of low pressure fluids when high mass flow rate (higher cooling capacity) is considered.

Although methanol and FC 72 have the highest density ratios of the fluids analyzed in FIG. 9, which means a potentially higher mass flow rate in a thermosiphon loop cooling system, their pressure drops are similar to the values obtained for R245fa and R1233zd (E) at low mass flow rates and higher at high mass flow rates. Thus, the potential benefit associated with the higher density ratio is offset by a higher pressure drop.

For single-phase cooling where latent heat cannot be used, the relevant parameters are the specific heat (higher values mean higher cooling capacity when considering constant mass flow rate and gradient of fluid temperature) as well as viscosity (associated with the cooling system pressure drop and, consequently, pumping power in a pumped cooling system). The dielectric fluids R134a, R1234yf, R1234ze, R245fa and Novec 7000 show the highest values of specific heat according to Table 1, however R245fa and Novec 7000 have higher values of liquid viscosity, which means higher pressure drop and pumping power. In fact, the fluids CO₂, ethanol, methanol show the highest values of specific heat according to Table 1, however, aspects such as high pressure (CO₂), sub-atmospheric pressures (Ethanol, Methanol), high viscosity (Ethanol, Methanol), flammability (Ethanol, Methanol) and toxicity (Methanol) considerably limit the use of these fluids.

Comparing single-phase with two-phase cooling, the latter has the advantage of naturally maintaining a more uniform temperature of the heat source (for example component to be cooled) due to the saturation process. Also, a lower mass flow rate and pumping power (when considering an actively pumped cooling system) are possible, since single-phase systems need higher values of mass flow rates to guarantee a minimum in the gradient of temperature along the surface to be cooled and, consequently, a uniform temperature of the opto-mechanical components, systems and structures.

When considering the fluids R134a, Novec 7000 and water, wherein the first is used for two-phase cooling and assuming that 40% of the latent heat is used (40% vapor quality at the outlet of the evaporator), and the other two for single-phase cooling and considering a temperature gradient of 3° C., the mass flow rate will be respectively 2.53 kgh⁻¹, 46.2 kgh⁻¹ and 14.3 kgh⁻¹ for a cooling capacity of 50 W, which means a lower pumping power consumption when considering two-phase cooling.

The critical temperature and critical pressure (see Table 1) show that all the fluids listed in Table 1 are possible to be applied in the thermodynamic condition of interest, i.e. at a temperature of around 22° C. Special attention is required for CO₂, since above 31° C. it works in a super-critical region, where distinct liquid and gaseous phases do not exist. The triple point is also an important parameter to be taken into account, since during transport of a final product negative ambient temperatures can be achieved and a working fluid can solidify, consequently damaging the cooling system. For the fluids R1234yf, Novec 7300, FC 72, FC 43, FC 3283, CO₂ and water the triple point is relatively high and these fluids could freeze during shipping of such systems in cold weather.

Further, considering the global warming potential (GWP), the best fluids after water are CO₂, R1233zd (E), R1234yf, R1234ze, Novec 649 and Novec 774.

In order to summarize the foregoing, for two-phase flow and passive cooling systems (e.g. thermosiphon loop systems), R245fa and R1233zd (E) are the most advantageous dielectric fluids to be used as the cooling medium 92, which showed a low pressure drop for a range of relatively high mass flow rates, and a high density ratio.

For an actively pumped cooling system, two-phase cooling has a high uniformity in temperature of the cooling medium (due to the latent heat transfer, and consequently very uniform temperature of the components to be cooled) and also low pumping power. The working fluids R1233zd (E), R1234yf, R1234ze, R236fa, R245fa, R134a and Novec 7000 present the highest values of latent heat, while the viscosity of R134a, R1234yf and R1234ze and, thus, the pressure drop in the system is lower than for Novec 7000.

For single-phase cooling, the dielectric fluid R134a is the most advantageous one after water, but without the shortcomings of water (high risk of damage of the optical system and electronics in the presence of leakage). R134a has a high specific heat and low viscosity which is essential in single-phase cooling. R134a has a saturation pressure of 6.08 bar at a temperature of 22° C., and thus, could be operated under an operating pressure between approximately 6.1 bar and approximately 10 bar.

TABLE 1

| | T sat | P sat | | | | 22° C. | | | |
|---|---|---|---|---|---|---|---|---|---|
| | @ | @ | Triple | | | | Viscosity | Liquid | Liquid |
| | 1bar | 22° C. | Point | T_{critical} | P_{critical} | Density | @ x = 0.4 | viscosity | density |
| | (° C.) | (bar) | (° C.) | (° C.) | (bar) | ratio | (μPas) | (μPas) | (kgm⁻³) |
| R134a | −26.4 | 6.08 | −103.3 | 101.1 | 40.59 | 41.2 | 126.0 | 202.3 | 1218.0 |
| R1233zd(E) | 18.4 | 1.14 | −78.0 | 165.6 | 37.72 | 201.9 | 289.6 | 475.4 | 1295.0 |
| R1234yf | −29.7 | 6.18 | −53.2 | 94.8 | 32.66 | 32.1 | 107.7 | 171.3 | 1107.4 |
| R1234ze | −18.5 | 4.45 | −104.5 | 109.6 | 36.81 | 49.1 | 130.7 | 209.6 | 1165.5 |
| R236fa | −1.75 | 2.46 | −93.6 | 124.9 | 32 | 82.2 | 182.2 | 296.5 | 1369.8 |
| R245fa | 14.8 | 1.32 | −102.1 | 154.1 | 154.1 | 175.2 | 258.0 | 423.3 | 1346.6 |
| Novec 649 | 49 | 0.35 | −108* | 169.0 | 18.8 | 371.9 | N/A | 608.0 | 1610.5 |
| Novec 7000 | 34 | 0.57 | −122* | 165.0 | 24.8 | 291.2 | N/A | 427.5 | 1409.2 |
| Novec 7100 | 61 | 0.24 | −135* | 195.0 | 22.3 | N/A | N/A | 551.0 | 1488.4 |
| Novec 7200 | 76 | 0.14 | −138* | 210.0 | 20.1 | N/A | N/A | 551.0 | 1430.4 |
| Novec 7300 | 98 | 0.05 | −38* | 243.0 | 18.8 | N/A | N/A | 1121.0 | 1663.4 |
| Novec 7500 | 128 | 0.02 | −100* | 261.0 | 15.5 | N/A | N/A | 1178.0 | 1619.9 |
| Novec 774 | 74 | 0.14 | −78* | 195.0 | 17.1 | N/A | N/A | 826.5 | 1767.6 |
| FC 72 | 56 | 0.27 | −90* | 176.0 | 18.3 | 439.6 | 245.2 | 608.0 | 1682.6 |
| FC 43 | 174 | 0.0016 | −50* | 294.0 | 11.3 | N/A | N/A | 4465.0 | 1865.0 |
| FC 70 | 215 | 0.0002 | −25* | 334.9 | 10.3 | N/A | N/A | 22800.0 | 1941.5 |
| FC 3283 | 128 | 0.0121 | −50* | 235.0 | 12.2 | N/A | N/A | 1330.0 | 1794.0 |
| Water | 100 | 0.0265 | 0.0 | 374.0 | 220.64 | 43206.9 | 538.0 | 890.1 | 1000.0 |
| CO₂ (R744) | — | 60.0 | −56.6 | 31.0 | 73.8 | 3.6 | 45.1 | 62.7 | 750.8 |
| Ethanol | 77.9 | 0.067 | −114.2 | 240.8 | 61.5 | 6263.2 | 693.0 | 1149.2 | 787.9 |
| Methanol | 64.1 | 0.145 | −97.5 | 239.5 | 81.0 | 4071.3 | 344.5 | 567.8 | 789.1 |

| | | | Dielectric | | |
|---|---|---|---|---|---|
| | Latent | Specific | strength | | |
| | heat @ | heat @ | for a | | |
| | 25° C. | 25° C. | 0.25 cm | Dielectric | |
| | (kJkg⁻¹) | (JK⁻¹kg⁻¹) | gap (kV) | constant | GWP |
| R134a | 177.8 | 1424.6 | 6.6 | ~10 | 1320 |
| R1233zd(E) | 191.1 | 1161.2 | N/A | N/A | 5 |
| R1234yf | 143.9 | 1379.7 | N/A | N/A | 4 |
| R1234ze | 167.1 | 1388.7 | 11.7 | N/A | 6 |
| R236fa | 145.9 | 1264.4 | N/A | 1.02 | 6300 |
| R245fa | 190.3 | 1322.1 | N/A | ~6 | 1020 |
| Novec 649 | 88.0 | 1103.0 | >40 | 1.80 | 1 |
| Novec 7000 | 142.0 | 1300.0 | ~40 | 7.40 | 420 |
| Novec 7100 | 112.0 | 1183.0 | ~40 | 7.40 | 297 |
| Novec 7200 | 119.0 | 1220.0 | ~40 | 7.30 | 59 |
| Novec 7300 | 102.0 | 1140.0 | ~40 | 6.10 | 210 |
| Novec 7500 | 89.0 | 1128.0 | ~40 | 5.80 | 90 |
| Novec 774 | 90.0 | 1130.0 | >40 | 1.90 | 1 |
| FC 72 | 88.0 | 1100.0 | 38 | 1.75 | 7400 |
| FC 43 | 70.0 | 1100.0 | 42 | 1.90 | 10000 |
| FC 70 | 69.0 | 1100.0 | 40 | 1.98 | 8900 |
| FC 3283 | 78.0 | 1100.0 | 43 | 1.89 | 8690 |
| Water | 2441.7 | 4181.6 | ~170** | 80** | 0 |
| CO₂ (R744) | 119.7 | 6467.4 | N/A | ~1.5 | 1 |
| Ethanol | 921.6 | 2573.9 | N/A | 2.43 | — |
| Methanol | 1169.0 | 2534.6 | N/A | 33.1 | — |

*pour point
**distilled water

1.-30. (canceled)

31. A system, comprising:
a component comprising a channel; and
a medium in the channel,
wherein:
the medium configured to absorb heat from the component during use of the system;
the medium comprises a dielectric fluid excluding pure water, 1,1,1,2-tetrafluoroethane and chlorodifluoromethane; and
the dielectric fluid comprises a liquid phase at a pressure below 10 bar and in a temperature range of approximately 10° C. to approximately 50° C.

32. The system of claim 31, wherein the medium is non-flammable.

33. The system of claim 31, wherein the dielectric fluid comprises a liquid phase at a pressure below 10 bar and in a temperature range of approximately 15° C. to approximately 35° C.

34. The system of claim 31, wherein the dielectric fluid comprises at least one member selected from the group consisting of:
trans-1-chloro-3,3,3-trifluoropropene;
2,3,3,3-tetrafluoropropene;
1,1,3,3,-tetrafluoropropene;
1,1,1,3,3,3-hexafluoropropane;
1,1,13,3-pentafluoropropane;
dodecafluoro-2-methylpentan-3-one;
1-methoxyheptafluoropropane;
methoxy-nonafluorobutane;
ethoxy- nonafluorobutane;
1,1,1,2,2,3,4,5,5,5-decafluoro-3-methoxy-4-(trfluoromethyl)-pentane;
3,ethoxy-1,1,1,2,3,4,4,5,5,6,6,6-dodecafluoro-2-(trifluoromethyl)-hexane;
tetradecafluoro-2-methylhexan-3-one tetradecafluoro-2,4-dimethylpentan-3-one;
1,1,1,2,2,3,3,4,4,5,5,6,6,6-tetradecafluorohexan;
perfluorotri-n-butylamine;
perfluorotripentylamine; and
perfluorotripropylamine.

35. The system of claim 31, wherein the dielectric fluid has a saturation pressure in a range between 0.08 bar and 10 bar at a temperature of approximately 22° C.

36. The system of claim 35, wherein the dielectric fluid comprises at least one member selected from the group consisting of:
trans-l-chloro-3,3,3-trifluoropropene;
2,3,3,3-tetrafluoropropene;
1,1, 3,3,-tetrafluoropropene;
1,1,1,3,3,3-hexafluoropropane; and
1,1,13,3-pentafluoropropane.

37. The system of claim 31, wherein the dielectric fluid is in the liquid phase only within the channel of the component.

38. The system of claim 31, wherein the dielectric fluid comprises liquid phase and gas phase within the channel of the component.

39. The system of claim 38, wherein the dielectric fluid comprises at least one member selected from the group consisting of trans-1-chloro-3,3,3-trifluoropropene and 1,1,1,3,3,3-hexafluoropropane.

40. The system of claim 31, wherein, within the channel of the component, the dielectric fluid is at approximately atmospheric pressure.

41. The system of claim 31, wherein the dielectric fluid in the channel has a temperature which is in a range of approximately 10° C. to approximately 50° C.

42. The system of claim 31, wherein the dielectric fluid has a boiling point in a temperature range of approximately 10° C. to approximately 50° C.

43. The system of claim 42, wherein the dielectric fluid comprises at least one member selected from the group consisting of:
trans-1-chloro-3,3,3-trifluoropropene;
1,1,13,3-pentafluoropropane;
dodecafluoro-2-methylpentan-3-one; and
1- methoxyheptafluoropropane.

44. The system of claim 31, wherein the dielectric fluid has a dielectric strength in a range of approximately 10 MV/m to approximately 70 MV/m.

45. The system of claim 31, wherein the dielectric fluid has a dynamic viscosity in a range of approximately 100 μPa·s to approximately 25000 μPa·s at a temperature of approximately 22° C. and at atmospheric pressure.

46. The system of claim 31, wherein the system configured so that, during use, the dielectric fluid has a mass flow rate of the medium is in the range of approximately 2 kg/h to approximately 30 kg/h.

47. The system of claim 31, wherein a pressure drop in the system is in a range of approximately 10 Pa to approximately 250 Pa.

48. The system of claim 31, wherein the system is configured so that, during use, a change of a pressure drop as a function of a mass flow rate is less than 8 Pa/(kg/h)).

49. The system of claim 31, wherein the system is a subsystem of an EUV microlithography projection exposure apparatus.

50. The system of claim 31, wherein the component comprises a mirror.

51. The system of claim 31, wherein the dielectric fluid is based on fluorocarbon, perfluorocarbon or hydrofluoroether.

52. The system of claim 31, wherein the channel is integrated into the system, the channel is a structure of the system, or the channel is integrated into the component.

53. A system, comprising:
a component comprising a channel; and
1,1,1,2-tetrafluoroethane in the channel,
wherein the 1,1,1,2-tetrafluoroethane is in the liquid phase only.

54. The system of claim 53, wherein the 1,1,1,2-tetrafluoroethane is at a pressure of more than approximately 6.1 bar and at a temperature in a range of approximately 10° C. to approximately 30° C.

55. The system of claim 54, wherein the 1,1,1,2-tetrafluoroethane is at a pressure of less than approximately 10 bar.

56. The system of claim 53, wherein the system configured so that, during use, the dielectric fluid has a mass flow rate of the 1,1,1,2-tetrafluoroethane is in the range of approximately 2 kg/h to approximately 30 kg/h.

57. The system of claim 53, wherein a pressure drop in the system is in a range of approximately 10 Pa to approximately 250 Pa.

58. The system of claim 53, the system is configured so that, during use, a change of a pressure drop as a function of a mass flow rate is less than 8 Pa/(kg/h)).

59. The system of claim 53, wherein the system is a subsystem of an EUV microlithography projection exposure apparatus.

60. The system of claim 53, wherein the component comprises a mirror.

61. A method, comprising:
flowing a dielectric fluid through a channel of a component of an EUV microlithography projection objective to remove heat from the component,
wherein the dielectric fluid excludes pure water, 1,1,1,2-tetrafluoroethane and chlorodifluoromethane; and
the dielectric fluid comprises a liquid phase at a pressure below 10 bar and in a temperature range of approximately 10° C. to approximately 50° C.
